(19) United States
(12) Patent Application Publication
(10) Pub. No.: US 2010/0182049 A1
(43) Pub. Date: Jul. 22, 2010

(54) Digital Phase Detection

(76) Inventor: Henrik Sjoland, Loddekopinge (SE)

Correspondence Address: POTOMAC PATENT GROUP PLLC, P. O. BOX 270, FREDERICKSBURG, VA, 22404, US

(21) Appl. No.: 12/357,986

(22) Filed: Jan. 22, 2009

(51) Int. Cl. G01R 25/00

(52) U.S. Cl. 327/7

(57) ABSTRACT

A method of detecting a phase difference between a circuit output signal and a reference signal is useful in all digital phase locked loops. A plurality of feedback signals are generated from the circuit output signal by means of a process that includes phase interpolation, wherein the feedback signals are spaced apart from one another by a duration of time less than a period of the circuit output signal. At a moment in time, the number of feedback signals that are asserted (logic 1 or in alternative embodiments, logic 0) is counted. The count is indicative of the phase difference between the circuit output signal and the reference signal.

### BACKGROUND

The present invention relates to phase locked loops, more particularly to all digital phase locked loops, and even more particularly to methods and apparatuses that perform digital phase detection in an all digital phase locked loop.

A phase-locked loop (PLL) is a circuit that generates an output signal having a fixed phase/frequency relation with respect to a supplied reference signal. This is achieved by feeding back the output signal to circuitry that compares the phase (time) of the feedback signal with that of the reference signal. A control signal is generated from the phase difference, which control signal controls the frequency/phase of a controllable oscillator that outputs the output signal. A frequency divider in the feedback path enables the frequency of the output signal to be a multiple of that of the reference signal.

Historically, PLL designs have utilized analog circuitry. An analog phase detector generates a pulse having a duration that corresponds to the phase/time difference between an edge of the reference signal and that of the feedback signal. A constant current source is connected to an analog loop filter during the pulse, and the charge injected is thereby proportional to the phase difference. An oscillator control signal can then be generated, for example, in the form of a voltage proportional to the accumulated charge.

A problem is presented in that it is difficult for such analog designs to reach sufficient dynamic range in modern CMOS processes because of the reduced supply voltages. Analog filters have the additional disadvantage of occupying a significant chip area.

Thus, there is presently great interest in designs for All Digital PLLs (ADPLLs). In modern CMOS processes, digital circuits are fast and require only small chip area. Furthermore, using a digital implementation enables more advanced algorithms to be used that enable phase lock to be achieved more quickly. When a digital loop filter is used in a PLL, the building block before it, the phase detector, must produce a digital output signal. Similarly, the building block after the filter, the oscillator, must accept a digital control signal.

A high performance ADPLL design is described in R. B. Staszewski and P. T. Balsaras, “All-Digital Frequency Synthesizer in Deep-Submicron CMOS”, Wiley, 2006. The phase detector described therein uses a so-called time-to-digital converter, TDC, to achieve high phase resolution. This is combined with a counter that counts radio frequency (RF) clock cycles to obtain coarse resolution of the detected phase difference.

The TDC employs delay lines that are formed by chains of inverters.

A problem with this and similar designs is that the resolution is limited to one inverter delay. To obtain a finer resolution, complex circuitry is needed.

Another problem with this and similar designs is that the delay of the delay cells in the TDC suffers from large process, voltage, and temperature variations. The process variations translate into gain variations of the PLL open loop transfer function. If these gain variations are uncompensated, the PLL suffers from detrimental variations in stability and bandwidth. Measures for compensation have therefore been developed, but this too requires complex circuitry. Both open loop and closed loop designs have been employed.

Yet another problem with the use of TDCs is that mismatches between inverter delays can occur, which result in non-linearities, which are more difficult to correct.

It is therefore desired to provide high performance ADPLL methods and apparatuses that avoid problems associated with conventional designs.

### SUMMARY

It should be emphasized that the terms “comprises” and “comprising”, when used in this specification, are taken to specify the presence of stated features, integers, steps or components; but the use of these terms does not preclude the presence or addition of one or more other features, integers, steps, components or groups thereof.

In accordance with one aspect of the present invention, the foregoing and other objects are achieved in methods and apparatuses that detect a phase difference between a circuit output signal and a reference signal. Phase difference detection involves generating a plurality of feedback signals from the circuit output signal by means of a process that includes phase interpolation, wherein the feedback signals are spaced apart from one another by a duration of time less than a period of the circuit output signal. At a given moment in time, a count value is generated by counting the number of feedback signals that are asserted. This count is indicative of the phase difference. The moment in time can be, for example, an edge (trailing or leading) of the reference signal.

In some embodiments, generating the plurality of feedback signals from the circuit output signal comprises generating a plurality of frequency divided signals from the circuit output signal. Here, each of the frequency divided signals has a frequency corresponding to a frequency of the circuit output signal divided by N. Further, the frequency divided signals are offset in phase relative to one another by an amount equal to the period of the circuit output signal. In some embodiments, N is set equal to an integer value. In alternative embodiments, N is modulated to achieve a non-integer frequency division of the circuit output signal.

Some embodiments include generating interpolated signals from the frequency divided signals, wherein the interpolated signals are spaced apart from one another by a duration of time less than the period of the circuit output signal.

In some embodiments, counting how many of the feedback signals are asserted comprises counting how many of the feedback signals are at a logic one level. In alternative embodiments, counting how many of the feedback signals are asserted comprises counting how many of the feedback signals are at a logic zero level.

In some embodiments, counting how many of the feedback signals are asserted is performed by a digital thermometer-to-binary converter.

Embodiments of the phase detection methods and apparatuses are usefully applied in phase-locked loops. Such embodiments can further include generating a control signal for a digitally controlled oscillator from the count value.

In some embodiments, generating the control signal for the digital oscillator from the count value comprises inverting the sign of the count value.

### BRIEF DESCRIPTION OF THE DRAWINGS

The objects and advantages of the invention will be understood by reading the following detailed description in conjunction with the drawings in which:

FIG. 1 is a block diagram of an exemplary embodiment of an ADPLL in accordance with aspects of the invention.

FIG. 2 is a signal timing diagram illustrating an exemplary relationship between the PLL output signal, a first frequency divider output signal FBₚₕᵢ₁, and a second frequency divider output signal FBₚₕᵢ₂.

FIG. 3 is a signal timing diagram of the first and second frequency divider output signals, FBₚₕᵢ₁ and FBₚₕᵢ₂, and exemplary interpolated signals, FBᵢₙₜₑᵣₚ₁, . . . , FBᵢₙₜₑᵣₚ₆, generated by an exemplary embodiment of the phase interpolator.

FIG. 4 is a block diagram of an exemplary embodiment of the digital phase detector in accordance with aspects of the invention.

FIG. 5 is, in one respect, a flow diagram of steps/processes carried out to detect phase in accordance with some embodiments of the invention.

### DETAILED DESCRIPTION

The various features of the invention will now be described with reference to the figures, in which like parts are identified with the same reference characters.

The various aspects of the invention will now be described in greater detail in connection with a number of exemplary embodiments. To facilitate an understanding of the invention, many aspects of the invention are described in terms of sequences of actions to be performed by elements of a computer system or other hardware capable of executing programmed instructions. It will be recognized that in each of the embodiments, the various actions could be performed by specialized circuits (e.g., discrete logic gates interconnected to perform a specialized function), by program instructions being executed by one or more processors, or by a combination of both. Moreover, the invention can additionally be considered to be embodied entirely within any form of computer readable carrier, such as solid-state memory, magnetic disk, or optical disk containing an appropriate set of computer instructions that would cause a processor to carry out the techniques described herein. Thus, the various aspects of the invention may be embodied in many different forms, and all such forms are contemplated to be within the scope of the invention. For each of the various aspects of the invention, any such form of embodiments may be referred to herein as “logic configured to” perform a described action, or alternatively as “logic that” performs a described action, or “means for” performing a described function. As used herein, the term “circuitry” encompasses not only “logic”, as that term is defined above, but also analog circuits and/or circuit components.

In an aspect of embodiments consistent with the invention, digital phase detection methods and apparatuses are provided that do not use delay lines in the phase detector. To achieve high performance, two or more frequency divided PLL output signals are generated, each separated by an integer number of RF clock cycle times. This can easily be accomplished by means of digital circuitry. In another aspect, these two or more frequency divided signals are then subjected to phase interpolation. The result is a plurality of feedback signals with close and equal spacing. At the cost of complexity and power consumption, arbitrarily many signals can be generated. The resolution is thus not limited by one inverter delay.

In another aspect of embodiments consistent with the invention, the two or more feedback signals are compared to the PLL reference signal in the phase detector. The number of signals that are logic zero (or logic one) at the time of the reference signal edge is then a digital measure of the phase.

An advantage of this approach is the elimination of any need to compensate for process variations, since the phase detection range is fixed by the timing of the signals from the frequency divider.

These and other aspects will now be described in greater detail in the following.

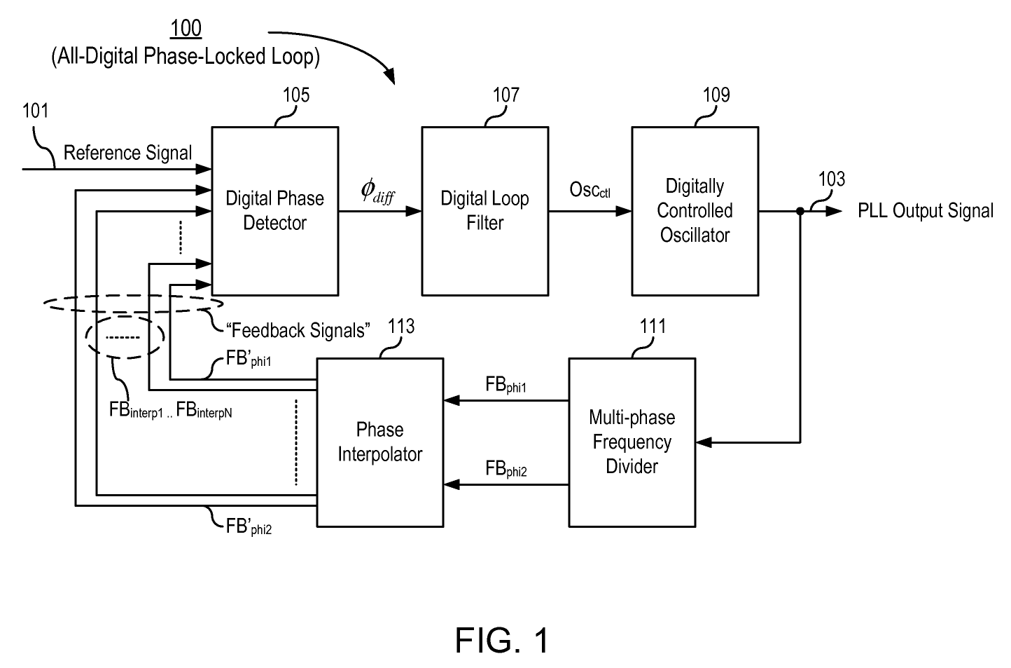

FIG. 1 is a block diagram of an exemplary embodiment of an ADPLL 100 in accordance with aspects of the invention. The ADPLL 100 receives a reference signal 101 and generates therefrom a PLL output signal 103 having a predetermined phase/frequency relationship with respect to the reference signal 101. The reference signal 101 is supplied to a digital phase detector 105 that determines the phase difference between the reference signal 103 and a frequency divided version of the PLL output signal 103, and generates a digital phase difference signal, φ_{diff}, representing this phase difference. How it does this is described in further detail below. The digital phase difference signal, φ_{diff}, is supplied to a digital loop filter 107 that generates a digital control signal, Osc_{CTL}, as a function of the digital phase difference signal, φ_{diff}. The digital control signal, Osc_{CTL}, is supplied to a control input of a digitally controlled oscillator 109 that generates the PLL output signal 103. The purpose of the digital control signal, Osc_{CTL}, is to control the digitally controlled oscillator 109 in a manner that causes the frequency of the PLL output signal 103 to have a desired relationship with respect to the frequency of the reference signal 101. The digital loop filter 107 and the digitally controlled oscillator 109 can each be embodied in any of a number of known ways, no one of which is essential to the invention.

As mentioned earlier, PLLs require a feedback path to enable the control function (i.e., to ensure that the oscillator is controlled in a manner that maintains the desired relationship with respect to the reference signal). In an aspect of embodiments consistent with the invention, the PLL output signal 103 is supplied to circuitry configured to generate a plurality of feedback signals spaced apart from one another in phase. The spacing of these signals is close and preferably (but not necessarily) equal, such that the phase difference between any two consecutive feedback signals is less than the period of the PLL output signal 103.

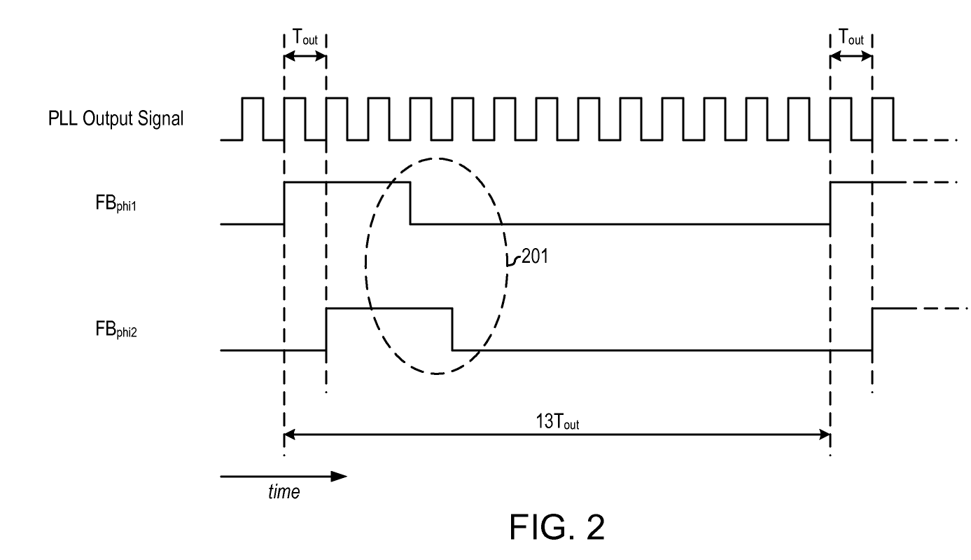

To illustrate how such feedback signals can be formed from the PLL output signal 103, the exemplary ADPLL 100 includes a multi-phase frequency divider 111 and a phase interpolator 113 in the feedback path. The PLL output signal 103 is supplied to an input port of the multi-phase frequency divider 111, which generates an output signal having a frequency that is a desired fraction of the frequency of the PLL output signal 103. In some embodiments, the divisor can be a fixed value; in other embodiments, it can be changed dynamically. Frequency division is well-known in the art, and need not be described in further detail. However, unlike typical frequency dividers, the multi-phase frequency divider 111 generates two frequency divider output signals, FBₚₕᵢ₁ and FBₚₕᵢ₂, that are separated in phase with respect to one another by an amount equal to an integer number (e.g., 1) of periods of the PLL output signal 103. This means that the second frequency divider output signal, FBₚₕᵢ₂, is a time delayed (or alternatively time advanced) version of the first frequency divider output signal, FBₚₕᵢ₁. In other respects, however, each of the frequency divider output signals, FBₚₕᵢ₁ and FBₚₕᵢ₂, represents a frequency-divided version of the PLL output signal 103. FIG. 2 is a signal timing diagram illustrating the relationship between the PLL output signal 103, a first frequency divider output signal FBₚₕᵢ₁, and a second frequency divider output signal FBₚₕᵢ₂ for the case in which the multi-phase frequency divider 111 performs a divide-by-13 function. It will be recognized that dividing by 13 is not an essential aspect of the invention, and that alternative embodiments can involve dividing by any integer number. It will be appreciated that, in some applications, it is desired to use fractional frequency dividers in a PLL feedback path. Such embodiments are also viable in accordance with the inventive principles since fractional frequency division is typically accomplished by means of dividing the frequency of PLL output signal by an integer amount that is made to vary over time in a way such that, on average, the frequency of the frequency divider output is that which would have been achieved by means of fractional frequency division. What this means is that, at any given moment, the frequency divider is dividing by an integer amount regardless of whether it is being employed to accomplish fractional frequency division.

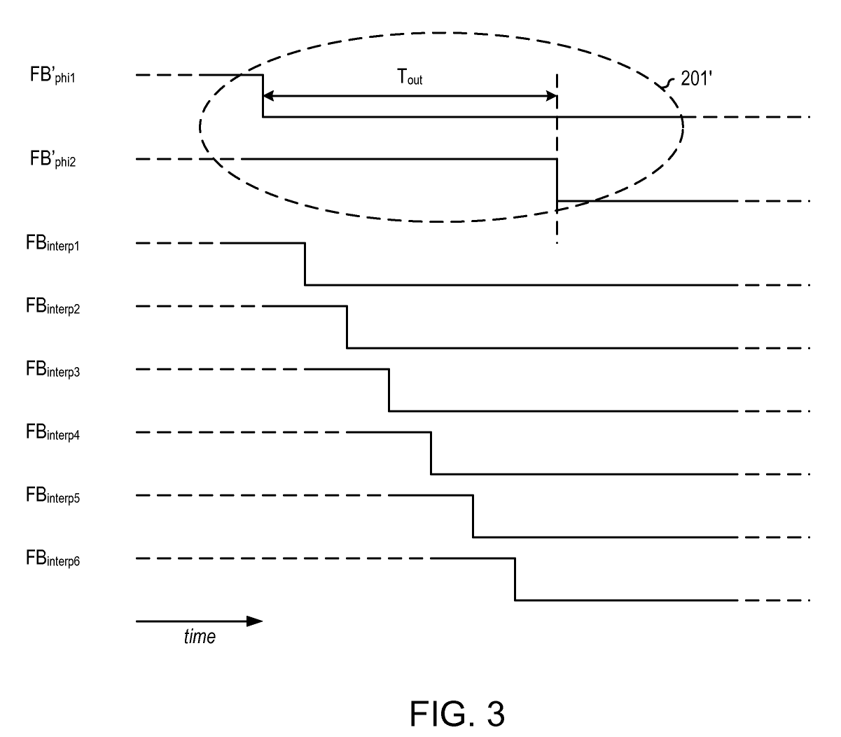

As can be seen in the figure, the exemplary PLL output signal 103 has a period denoted Tₒᵤₜ, whereas each of the first and second frequency divider output signals, FBₚₕᵢ₁ and FBₚₕᵢ₂, has a period given by 13Tₒᵤₜ. As further illustrated, the first and second frequency divider output signals, FBₚₕᵢ₁ and FBₚₕᵢ₂, are out of phase from one another by an amount Tₒᵤₜ, which corresponds to the period of the PLL output signal 103. To further illustrate an aspect of embodiments consistent with the invention, trailing edges of the first and second frequency divider output signals, FBₚₕᵢ₁ and FBₚₕᵢ₂, are denoted by the reference symbol 201, and counterparts of these portions of the signals (denoted 201′) are illustrated in FIG. 3, which is described below.

It is desired to be able to resolve phase differences with a granularity smaller than the period of the PLL output signal 103. Thus, a plurality of feedback signals 115 are derived from the first and second frequency divider output signals, FBₚₕᵢ₁ and FBₚₕᵢ₂, by supplying the first and second frequency divider output signals, FBₚₕᵢ₁ and FBₚₕᵢ₂ as inputs to a phase interpolator 113. The phase interpolator 113 passes the first and second frequency divider output signals, FBₚₕᵢ₁ and FBₚₕᵢ₂, through to respective phase interpolator output ports at which they appear as delayed versions of the first and second frequency divider output signals, herein denoted FB′ₚₕᵢ₁ and FB′ₚₕᵢ₂. The delay is attributable to circuit delays within the phase interpolator 113, and is sufficiently large so that the original and delayed signals are measurably out of phase with one another. The phase interpolator 113 also generates two or more signals, FBᵢₙₜₑᵣₚ₁, . . . , FB_{interpN}, having transition times between those of the delayed first and second frequency divider output signals, FB′ₚₕᵢ₁ and FB′ₚₕᵢ₂. Phase interpolator circuits are known in the art and are conventionally used, for example, to generate multi-phase clock signals when such signals are needed in any of a number of different digital environments. The interested reader can find descriptions of interpolator circuits in T. Saeki, M. Mitsuishi, H. Iwaki, M. Tagishi, “A 1.3-Cycle Lock Time, Non-PLL/DLL Clock Multiplier Based on Direct Clock Cycle Interpolation for Clock on Demand”, IEEE Journal of Solid-State Circuits, Vol. 35, No. 11, November 2000, pp. 1581-1590; and in L. Yang and J. Yuan, “An Arbitrarily Skewable Multiphase Clock Generator Combining Direct Interpolation with Phase Error Average”, In proceedings of International Symposium of Circuits and Systems (ISCAS) 2003, May 2003, Volume 1, pp. 645-648.

FIG. 3 is a signal timing diagram of portions (denoted 201′) of the delayed first and second frequency divider output signals, FB′ₚₕᵢ₁ and FB′ₚₕᵢ₂, supplied at the phase interpolator output port. FIG. 3 also illustrates exemplary interpolated signals, FBᵢₙₜₑᵣₚ₁, . . . , FBᵢₙₜₑᵣₚ₆, generated by an exemplary embodiment of the phase interpolator 113. It will be appreciated that in alternative embodiments, the phase interpolator 113 can generate more or fewer interpolated signals than the six shown in the figure. A characteristic of the interpolated signals is that they are spaced apart from one another by a duration of time that is less than the period of the PLL output signal 103. The interpolated signals are preferably equally spaced apart from one another, but this is not an essential aspect of the invention. As to the number of interpolated signals that should be generated for any given embodiment, the tradeoff is more power consumption for higher resolution (i.e., more interpolated signals). Thus, it is advantageous to generate no more interpolated signals than are necessary to achieve a desired phase detector resolution level.

The output signals of the phase interpolator 113 (i.e., FBᵢₙₜₑᵣₚ₁, . . . , FB_{interpN}, and delayed first and second frequency divider output signals, FBₚₕᵢ₁ and FBₚₕᵢ₂), are supplied as feedback signals to respective inputs of the digital phase detector 105. The digital phase detector 105 operates by comparing the timing of the edges of the feedback signals to that of the reference clock edge. In some embodiments, this is accomplished by sampling the feedback signals at the edge of the reference clock. The phase measurement is then obtained by simply counting how many of the feedback signals are logic one (or in alternative embodiments, logic zero) at the moment of sampling. The count is indicative of the measured phase difference and, depending on design, may include a fixed offset. The offset will not be an issue in most PLL designs, but in case it is, it can easily be subtracted from the count value to arrive at offset-free phase detection.

How the count is interpreted will depend on the particular embodiment. For example, when counting logic zeroes on the falling edge of the feedback signals or counting logic ones on the rising edge of the feedback signals, there is a positive relation between the count value and the phase relation: the higher the count, the greater the phase difference. By contrast, when counting logic ones on the falling edge of the feedback signals or counting logic zeroes on the rising edge of the feedback signals, there is a negative relation between the count value and the phase relation: the higher the count, the lower the phase difference. Which of these four possibilities (counting logic ones on the falling edge; counting logic zeroes on the falling edge; counting logic ones on the rising edge; counting logic zeroes on the rising edge) is the case for any given embodiment is a design choice. The designer can, for example, implement the phase detector 105 to count logic ones and for the digital loop filter 107 to be non-inverting (i.e., to use count value directly), in which case the PLL will reach stability on the falling edge of the feedback signals (the PLL will be unstable when relying on count values obtained on the rising edge of the feedback signals). Alternatively, an inverting digital loop filter 107 can be used (i.e., one that multiplies the count by “minus 1”), in which case the PLL will reach stability on the falling edge of the feedback signals when the phase detector 105 is constructed to count logic zeroes. Two more embodiments are possible; that is, counting logic ones when an inverting digital loop filter 107 is employed, or counting logic zeroes when a non-inverting digital loop filter 107 is employed. For each of these last two embodiments, stable PLL operation occurs on the rising edge of the feedback signals. A number of different techniques can be used to assist loop acquisition for any of these four embodiments, including but not limited to detection of frequency error.

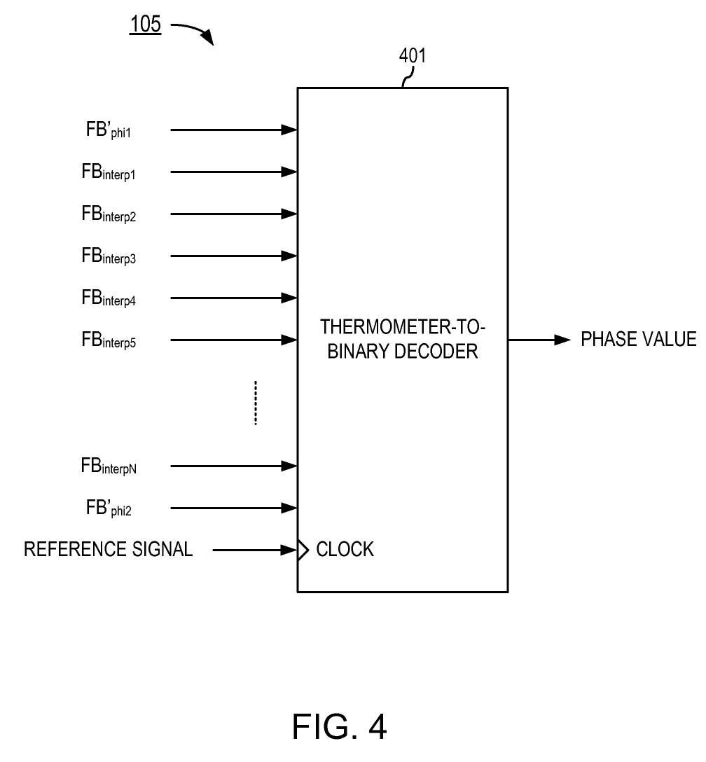

FIG. 4 is a block diagram of an exemplary embodiment of the digital phase detector 105. The feedback signals are supplied to respective ones of a number of input ports of a digital thermometer-to-binary decoder 401. A digital thermometer decoder is a circuit that typically is used to receive a set of signals, each corresponding to one segment of a thermometer display. The thermometer signals are activated such that assertion of only a lowest segment indicates a lowest temperature, assertion of the two lowest segments indicates a slightly higher than lowest temperature, assertion of the three lowest segments indicates a temperature that is higher still, and so on. Since the feedback signals are also asserted in this pattern, in accordance with an aspect of the invention, the thermometer-to-binary decoder 401 is advantageously used to convert the feedback signals directly into a binary phase value. The reference signal 101 is applied to a clock input of the digital thermometer-to-binary decoder 401. This causes the digital thermometer-to-binary decoder 401 to sample and count the feedback signals only at the moment of an edge (e.g., rising or falling edge) of the reference clock 101. The count value is then maintained at the output of the digital thermometer-to-binary decoder 401 until the next sampling/counting time.

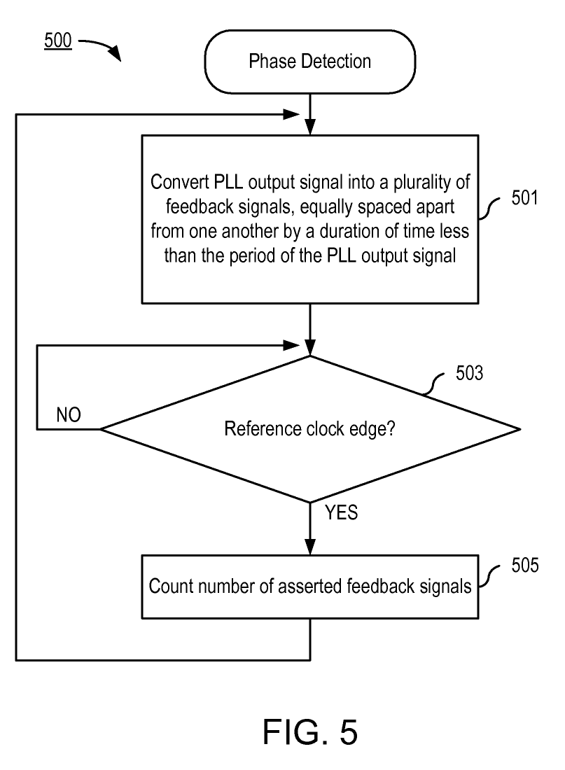

FIG. 5 is, in one respect, a flow diagram of steps/processes carried out to detect phase in accordance with some embodiments of the invention. In another respect, FIG. 5 can be considered to depict logic configured to detect phase 500 in accordance with other embodiments of the invention.

Phase detection begins by converting the PLL output signal 103 into a plurality of feedback signals that are equally spaced apart from one another by a duration of time less than the period of the PLL output signal 103 (step 501). The PLL output signal 103 is first subjected to frequency division to enable the PLL output signal 103 to have a frequency that is a pre-defined multiple of the frequency of the reference signal 101.

The feedback signals are not analyzed for so long as there is no relevant (e.g., rising or falling) edge of the reference clock (“NO” path out of decision block 503). However, when a relevant edge of the reference clock does occur (“YES” path out of decision block 503), the number of asserted feedback signals is counted (step 505). As explained earlier, depending on whether logic ones are counted or logic zeroes are counted and on whether the PLL is designed to operate on the rising or falling edge of the feedback signals, the count will represent a positive or negative phase difference (possibly with a fixed offset). Since FIG. 5 depicts only those steps associated with phase detection, subsequent steps performed in a digital loop filter, such as inverting the count in embodiments that generate negative phase differences, are not shown.

Having determined the phase difference at one edge of the reference clock 101, the process then repeats, beginning at step 501.

Embodiments consistent with the invention provide advantages in that problems associated with conventional techniques can be circumvented or reduced. Embodiments are not dependent on process variations because the digital divider fixes the phase detection range to a number of RF clock cycles (e.g., 1 or 2).

Another advantage is that the resolution is not limited by the delay of an inverter because it is possible to generate an arbitrary number of phases. Of course in practice, there are limitations set by power consumption and chip area. It should also be recognized that, although the obtainable resolution can be very high, there are nonetheless limits to the accuracy due to nonlinearities. The linearity, which suffers due to inverter delay mismatches, can be improved in the phase interpolator by using phase error averaging.

The invention has been described with reference to particular embodiments. However, it will be readily apparent to those skilled in the art that it is possible to embody the invention in specific forms other than those of the embodiment described above. The described embodiments are merely illustrative and should not be considered restrictive in any way. The scope of the invention is given by the appended claims, rather than the preceding description, and all variations and equivalents which fall within the range of the claims are intended to be embraced therein.

What is claimed is:

1. A method of detecting a phase difference between a circuit output signal and a reference signal, the method comprising:
generating a plurality of feedback signals from the circuit output signal by means of a process that includes phase interpolation, wherein the feedback signals are spaced apart from one another by a duration of time less than a period of the circuit output signal; and
at a moment in time, generating a count value by counting how many of the feedback signals are asserted, whereby the count value is indicative of the phase difference between the circuit output signal and the reference signal.

2. The method of claim 1, wherein generating the plurality of feedback signals from the circuit output signal comprises:
generating a plurality of frequency divided signals from the circuit output signal, wherein each of the frequency divided signals has a frequency corresponding to a frequency of the circuit output signal divided by N, and wherein the frequency divided signals are offset in phase relative to one another by an amount equal to an integer number of periods of the circuit output signal.

3. The method of claim 2, comprising setting N equal to an integer value.

4. The method of claim 2, comprising modulating N to achieve a non-integer frequency division of the circuit output signal.

5. The method of claim 2, comprising:
generating interpolated signals from the frequency divided signals, wherein the interpolated signals are spaced apart from one another by a duration of time less than the period of the circuit output signal.

6. The method of claim 1, wherein counting how many of the feedback signals are asserted comprises:
counting how many of the feedback signals are at a logic one level.

7. The method of claim 1, wherein counting how many of the feedback signals are asserted comprises:
counting how many of the feedback signals are at a logic zero level.

8. The method of claim 1, wherein counting how many of the feedback signals are asserted is performed by a digital thermometer-to-binary converter.

9. The method of claim 1, wherein the circuit output signal is an output signal from a phase-locked loop.

10. The method of claim 9, comprising generating a control signal for a digitally controlled oscillator from the count value.

11. The method of claim 10, wherein generating the control signal for the digital oscillator from the count value comprises inverting the sign of the count value.

12. The method of claim 1, wherein the moment in time corresponds to a leading or trailing edge of the reference signal.

13. An apparatus for detecting a phase difference between a circuit output signal and a reference signal, the apparatus comprising:
circuitry configured to generate a plurality of feedback signals from the circuit output signal by means of a process that includes phase interpolation, wherein the feedback signals are spaced apart from one another by a duration of time less than a period of the circuit output signal; and
logic configured to generate a count value at a moment in time by counting how many of the feedback signals are asserted, whereby the count value is indicative of the phase difference between the circuit output signal and the reference signal.

14. The apparatus of claim 13, wherein the circuitry configured to generate the plurality of feedback signals from the circuit output signal comprises:
logic configured to generate a plurality of frequency divided signals from the circuit output signal, wherein each of the frequency divided signals has a frequency corresponding to a frequency of the circuit output signal divided by N, and wherein the frequency divided signals are offset in phase relative to one another by an amount equal to an integer number of periods of the circuit output signal.

15. The apparatus of claim 14, comprising logic configured to set N equal to an integer value.

16. The apparatus of claim 14, comprising logic configured to modulate N to achieve a non-integer frequency division of the circuit output signal.

17. The apparatus of claim 14, comprising:
circuitry configured to generate interpolated signals from the frequency divided signals, wherein the interpolated signals are spaced apart from one another by a duration of time less than the period of the circuit output signal.

18. The apparatus of claim 13, wherein the logic configured to count how many of the feedback signals are asserted comprises:
logic configured to count how many of the feedback signals are at a logic one level.

19. The apparatus of claim 13, wherein the logic configured to count how many of the feedback signals are asserted comprises:
logic configured to count how many of the feedback signals are at a logic zero level.

20. The apparatus of claim 13, wherein the logic configured to count how many of the feedback signals are asserted is a digital thermometer-to-binary converter.

21. The apparatus of claim 13, wherein:
the apparatus is an element in a phase-locked loop; and
the circuit output signal is an output signal from the phase-locked loop.

22. The apparatus of claim 21, comprising:
a digitally controlled oscillator; and
logic configured to generate a control signal for the digitally controlled oscillator from the count value.

23. The apparatus of claim 22, wherein the logic configured to generate the control signal for the digital oscillator from the count value comprises logic configured to invert the sign of the count value.

24. The apparatus of claim 13, wherein the moment in time corresponds to a leading or trailing edge of the reference signal.
